(19) United States
(12) Patent Application Publication
(10) Pub. No.: US 2017/0223862 A1
(43) Pub. Date: Aug. 3, 2017

(54) REPOSITIONABLE STAND FOR PORTABLE ELECTRONIC DEVICE

(71) Applicant: Distil Union, LLC, Charleston, SC (US)

(72) Inventors: Nate B. Justiss, Charleston, SC (US); Lindsay K. Windham, Charleston, SC (US)

(21) Appl. No.: 15/393,759

(22) Filed: Dec. 29, 2016

Related U.S. Application Data
(60) Provisional application No. 62/290,868, filed on Feb. 3, 2016.

(51) Int. Cl. H05K 7/18; F16M 11/38; F16M 11/20; A47B 97/00; A47B 23/04

(52) U.S. Cl. CPC H05K 7/18; A47B 97/00; A47B 23/043; F16M 11/2021; F16M 11/38; A47B 2097/005

(57) ABSTRACT

A repositionable stand for a portable electronic device includes at least one manually bendable layer material (e.g., sheet steel) forming bendable regions extending between multiple rigid body elements, and further includes a support platform proximate to one end. The bendable regions permit the stand to be arranged in a variety of positions. The support platform, which may be bendable, is suitable for securely receiving portable electronic devices of various thicknesses, and may include a forked end including peripheral regions separated by a medial gap to permit a portable electronic device receive a charging cable.

### STATEMENT OF RELATED APPLICATIONS

This application claims the benefit of provisional patent application Ser. No. 62/290,868, filed Feb. 3, 2016, the disclosure of which is hereby incorporated herein by reference in its entirety.

### TECHNICAL FIELD

The present disclosure relates to apparatuses for holding portable electronic devices such as mobile telephones and handheld portable digital media terminals.

### BACKGROUND

Portable electronic devices such as mobile phones, tablet computers, and portable digital media terminals have been widely adopted and are used by hundreds of millions of consumers on a daily basis. Numerous varieties of such devices have been developed, with various devices providing functions such as audio and video communication, audio and video playback, Web browsing, gaming, and social media interaction.

Portable electronic devices of numerous sizes, shapes, and thicknesses are available. Numerous protective cases have been developed for portable electronic devices to protect such devices from shock, scratches, dirt, and the like.

When not in active use, portable electronic devices are frequently carried by users in pockets, purses, and belt clips. When a user is stationary for a period of time (such as working at a desk), it may be desirable to position a portable electronic device in an upright position to permit the user to process video communication or engage in multimedia or gaming activities without continuously holding the device. It may also be desirable to simultaneously permit a portable electronic device to be connected to a charging cable.

Conventional stands for holding portable electronic devices suffer from limitations that affect their utility. For example, various rigid stands for holding portable electronic devices have been developed, such as the Elago M2 stand (available from Elago USA, San Diego, Calif.) fabricated of a single piece of rigid aluminum. However, such stands are not repositionable to accommodate different positions that may be desired by users at different times or in different contexts. Certain repositionable stands incorporating rotatable hinges have been developed, such as the aluminum-bodied Satechi R1 multi-angle hinge holder stand, but the ability of such stands to maintain desired positions may vary widely depending on factors such as hinge manufacturing variation, presence of moisture or dirt on hinge surfaces, and/or hinge wear. Numerous additional stands incorporating gooseneck-type continuously flexible arms have been developed, but such stands may be insufficiently compact or considered unsightly for some users. Additionally, conventional stands for holding portable electronic devices may be susceptible to receiving smudges or handprints, and may suffer from an undesirable (e.g., cold and hard) tactile feel when handled by users.

Accordingly, need exists in the art for improved stands for portable electronic devices to address limitations of conventional stands.

### SUMMARY

The present disclosure relates to a repositionable stand for a portable electronic device including at least one manually bendable layer material (e.g., sheet metal such as sheet steel) forming bendable regions extending between multiple rigid body elements, with the stand further including a support platform proximate to one end. The bendable regions permit the stand to be arranged in a variety of positions. The bendable support platform is suitable for securely receiving portable electronic devices of various thicknesses, and preferably includes a forked end including peripheral regions separated by a medial gap to permit a portable electronic device to be connected to a charging cable while supported by the stand. In certain embodiments, the support platform region is a bendable support platform, wherein a portion of the at least one manually bendable layer material extends beyond the first rigid body element to form the bendable support platform. In certain embodiments, surfaces of the repositionable stand may be covered with covering materials, such as leather, rubber, woven fabric, or non-woven fabric.

In one aspect, the present disclosure relates to a repositionable stand for a portable electronic device, the repositionable stand including a first end, a second end, a plurality of rigid body elements, at least one manually bendable layer material, and a support platform proximate to the first end. The plurality of rigid body elements includes first, second, and third rigid body elements that are spatially separated from one another and that are sequentially arranged between the first end and the second end. The at least one manually bendable layer material spans between the plurality of rigid body elements to form (i) a first bendable region between the first rigid body element and the second rigid body element, and (ii) a second bendable region between the second rigid body element and the third rigid body element.

In certain embodiments, the support platform region comprises a bendable support platform region, and a portion of the at least one manually bendable layer material extends beyond the first rigid body element to form the bendable support platform. In certain embodiments, the at least one manually bendable layer material includes at least one first sheet metal layer segment forming the first bendable region, at least one second sheet metal segment forming the second bendable region, and at least one third sheet metal segment forming the bendable support platform region. In certain embodiments, the at least one manually bendable layer material includes a single continuous sheet metal layer extending substantially an entire distance between the first end and the second end. In certain embodiments, the at least one manually bendable layer material includes sheet steel of a first thickness, the plurality of rigid body elements includes sheet steel of a second thickness, and the second thickness is greater than the first thickness. In certain embodiments, the at least one manually bendable layer material is affixed to the plurality of rigid body elements by adhering, brazing, or welding. In certain embodiments, a repositionable stand as described above includes a first covering material and a second covering material, wherein a combination of the at least one manually bendable layer material and the plurality of rigid body elements is arranged between the first covering material and the second covering material. In certain embodiments, the first covering material and the second covering material are each independently selected from the group consisting of leather, rubber, woven fabric, and non-woven fabric. In certain embodiments, the first rigid body element and the second rigid body element are separated by a first gap; the second rigid body element and the third rigid body element are separated by a second gap; and padding material (e.g., foam) is provided within the first gap between the first covering material and the second covering material, and is provided within the second gap between the first covering material and the second covering material. In certain embodiments, the padding material includes a thickness that is substantially the same as a thickness of the plurality of rigid body elements. In certain embodiments, the bendable support platform region includes a first peripheral region and a second peripheral region separated by a medial gap proximate to the first end. In certain embodiments, the second rigid body element defines an aperture, and the at least one manually bendable layer material defines an aperture that is registered with the aperture defined by the second rigid body element. Corresponding apertures registered with the foregoing apertures may also be defined in the covering material layers, with the resulting aperture defined through the entire stand being sized and shaped to permit passage of at least one charging and/or communication cable to be connected to a portable electronic device supported by the stand.

In another aspect, the present disclosure relates to a repositionable stand for a portable electronic device, the repositionable stand including a first end, a second end, a plurality of rigid body elements, and a manually bendable sheet metal layer. The plurality of rigid body elements includes first, second, and third rigid body elements that are spatially separated from one another and that are sequentially arranged between the first end and the second end. The manually bendable sheet metal layer is affixed to the plurality of rigid body elements and extends substantially an entire distance between the first end and the second end. A first portion of the manually bendable sheet metal layer forms a first bendable region between the first rigid body element and the second rigid body element, a second portion of the manually bendable sheet metal layer forms a second bendable region between the second rigid body element and the third rigid body element, and a third portion of the manually bendable sheet metal layer extends beyond the first rigid body element to form a bendable support platform region proximate to the first end.

In certain embodiments, the manually bendable sheet metal layer includes sheet steel of a first thickness, the plurality of rigid body elements includes sheet steel of a second thickness, and the second thickness is greater than the first thickness. In certain embodiments, the manually bendable sheet metal layer is affixed to the plurality of rigid body elements by adhering, brazing, or welding. In certain embodiments, a repositionable stand as described herein further includes a first covering material and a second covering material, wherein a combination of the manually bendable sheet metal layer and the plurality of rigid body elements is arranged between the first covering material and the second covering material. In certain embodiments, the first covering material and the second covering material are each independently selected from the group consisting of leather, rubber, woven fabric, and non-woven fabric. In certain embodiments, the first rigid body element and the second rigid body element are separated by a first gap; the second rigid body element and the third rigid body element are separated by a second gap; and padding material is provided within the first gap between the first covering material and the second covering material, and is provided within the second gap between the first covering material and the second covering material. In certain embodiments, the padding material includes a thickness that is substantially the same as a thickness of the plurality of rigid body elements. In certain embodiments, the bendable support platform region includes a first peripheral region and a second peripheral region separated by a medial gap proximate to the first end. In certain embodiments, the second rigid body element defines an aperture, and the manually bendable sheet metal layer defines an aperture that is registered with the aperture defined by the second rigid body element. Corresponding apertures registered with the foregoing apertures may also be defined in the covering material layers, with the resulting aperture defined through the entire stand being sized and shaped to permit passage of at least one charging and/or communication cable to be connected to a portable electronic device supported by the stand.

In another aspect, the present disclosure relates to methods of making and using a repositionable stand for a portable electronic device as described herein.

In additional aspects, any two or more of the foregoing aspects and/or any features or embodiments described herein may be combined for additional advantage.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWINGS

FIG. 1 is a perspective view illustration of a repositionable stand for a portable electronic device according to one embodiment, with the repositionable stand in a flat position and including superimposed transverse lines identifying boundaries between rigid regions and bendable regions.

FIG. 2 is a perspective view illustration of the repositionable stand with the superimposed transverse lines of FIG. 1, with the repositionable stand in a first upright bent position.

FIG. 3A is a perspective view illustration of the repositionable stand of FIGS. 1 and 2 according to one embodiment, with the repositionable stand in a second, low upright bent position.

FIG. 3B is a perspective view illustration of the repositionable stand of FIG. 3A in the second, low upright bent position, and with the repositionable stand supporting a portable electronic device represented in dashed lines.

FIGS. 4A-4E illustrate top plan view illustrations of five constituent layers of a repositionable stand for a portable electronic device according to one embodiment, in which FIG. 4A illustrates a first (e.g., outer) covering layer, FIG. 4B illustrates a bendable material layer, FIG. 4C illustrates rigid body elements of a rigid body layer, FIG. 4D illustrates padding sections of a padding material layer, and FIG. 4E illustrates a second (e.g., inner) covering layer.

FIG. 5 is a perspective assembly view illustration of five constituent layers of a repositionable stand for a portable electronic device according to one embodiment.

FIG. 6A is a side elevation view illustration of the repositionable stand of FIGS. 3A and 3B in the second, low upright bent position and supporting a portable electronic device.

FIG. 6B is a side elevation view illustration of the repositionable stand of FIG. 6A in the first upright bent position of FIG. 2 and supporting a portable electronic device.

FIG. 6C is a side elevation view illustration of the repositionable stand according to one embodiment in a range of three different positions supporting a portable electronic device.

FIG. 7A is a rear perspective view illustration of a repositionable stand according to one embodiment in the first upright bent position of FIG. 2 and supporting a portable electronic device.

FIG. 7B is a front perspective view illustration of the repositionable stand and portable electronic device shown in FIG. 7A.

FIG. 8A is a side elevation view illustration of a repositionable stand according to one embodiment in a third position and supporting a portable electronic device.

FIG. 8B is a side elevation view illustration of the repositionable stand and portable electronic device of FIG. 8A, with the repositionable stand being supported along an upper edge of a liquid crystal display monitor.

### DETAILED DESCRIPTION

The present disclosure relates to a repositionable stand for a portable electronic device including at least one manually bendable layer material (e.g., sheet metal such as sheet steel) forming bendable regions extending between multiple rigid body elements, and including a support platform region proximate to one end. Presence of bendable regions permits the stand to be arranged in a variety of positions without the use of pivotable hinges. A support platform region is intended to support a lower edge of a portable electronic device when present within the repositionable stand. In certain embodiments, the support platform region is bendable, suitable for securely receiving portable electronic devices of various thicknesses, and preferably includes a forked end including peripheral regions separated by a medial gap to permit a portable electronic device to be connected to a charging cable while supported by the stand. In certain embodiments, surfaces of the repositionable stand may be covered with covering materials, such as leather, rubber, woven fabric, or non-woven fabric. In certain embodiments, opposing surfaces of the repositionable stand may be covered with covering materials that differ from one another.

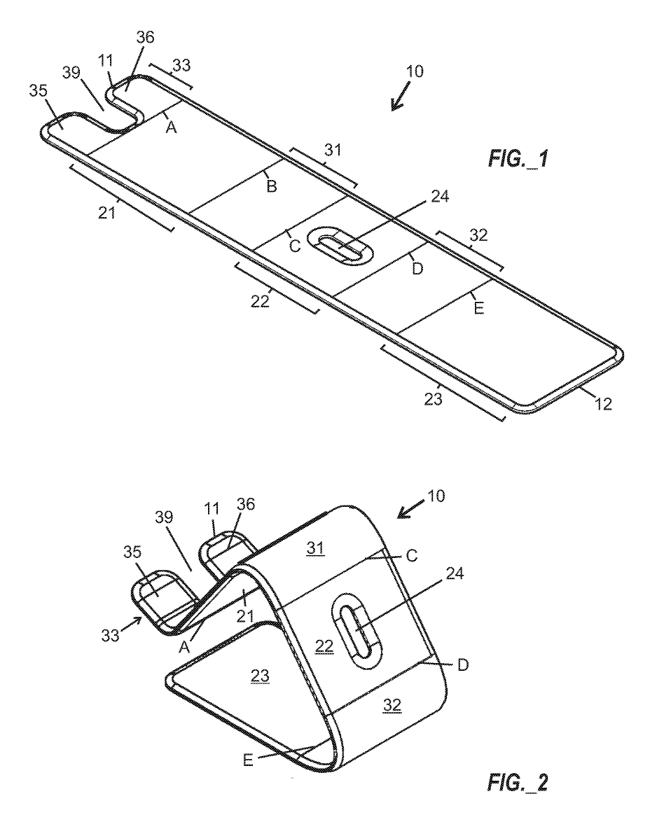

FIG. 1 illustrates a repositionable stand 10 for a portable electronic device according to one embodiment, with the repositionable stand 10 in a flat position and including five superimposed transverse lines A-E identifying boundaries between first through third rigid regions 21-23 and first through third manually bendable regions 31-33. The transverse lines A-E are provided for explanatory purposes only and may preferably be omitted from the repositionable stand 10. The repositionable stand 10 includes a first end 11 and a second end 12. Each manually bendable region 31-33 preferably includes at least one manually bendable layer material, e.g., a manually bendable sheet metal layer such as (but not limited to) twenty-four gauge sheet steel. Each rigid region 21-23 preferably includes a rigid body element that is substantially more rigid than each manually bendable region 31-33. In certain embodiments, each rigid region 21-23 includes a rigid body element, such as may include sheet metal (e.g., sheet steel) having a thickness that is substantially greater than a thickness of sheet metal of each manually bendable layer material. The rigid regions 21-23, which each include a rigid body element, are spatially segregated from one another (e.g., separated by manually bendable regions 31, 32) and sequentially arranged between the first end 11 and the second end 12.

One manually bendable region 33 proximate to the first end 11 includes a first peripheral region 35 and a second peripheral region 36 that are separated by a medial gap 39 that is configured to permit passage of at least one connector and/or cable to enable communication with and/or charging of a portable electronic device when such a device is supported by the repositionable stand 10. The manually bendable region 33 proximate to the first end 11 extends beyond a rigid body element of the first rigid region 21, and embodies a bendable support platform region 33. A central portion of the repositionable stand 10 defines an aperture 24 that is also sized and shaped to permit passage of at least one charging and/or communication cable to be connected to a portable electronic device when such a device is supported by the repositionable stand 10.

FIG. 2 is a perspective view illustration of the repositionable stand 10 and superimposed transverse lines A-E of FIG. 1, with the repositionable stand 10 in a first upright bent position, with the first and second manually bendable regions 31, 32 each having an acute bend angle of approximately sixty degrees, and with the bendable support platform region 33 including a single bend causing the bendable support platform region 33 to extend approximately ninety degrees outward relative to the first rigid region 21. In this configuration, a portable electronic device (not shown) may be supported from below by the bendable support platform region 33, and supported from behind by the first rigid region 21, while at least one communication and/or charging cord extends through the aperture 24 and the medial gap 39 to connect to a bottom edge of the portable electronic device.

In an alternative embodiment similar to the apparatus of FIG. 2, the support platform 33 may be non-bendable and permanently fixed in a position including at least one bend causing the support platform 33 to extend outward relative to the first rigid region 21. In certain embodiments, such a non-bendable support platform 33 may be an extension of the first rigid region 21. In certain embodiments, a non-bendable support platform 33 may include a single bend causing substantially an entire surface of the support platform 33 to extend outward in an approximately perpendicular direction relative to a face of the first rigid region 21. In other embodiments, a non-bendable support platform 33 may include a first bend causing an intermediate segment of the support platform 33 extend outward in an approximately perpendicular direction relative to a face of the first rigid region 21, and may include a second bend causing a tip segment of the support platform 33 to extend in a direction approximately parallel to a face of the first rigid region 21.

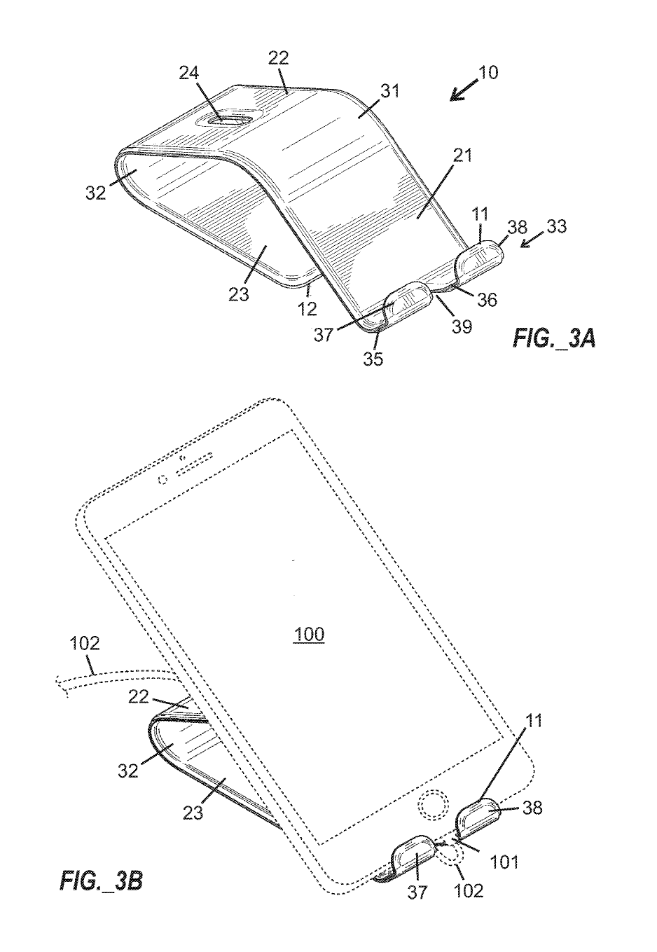

FIG. 3A illustrates a repositionable stand 10 for a portable electronic device according to one embodiment, with the repositionable stand 10 in a second, low upright bent position. Relative to the first upright position shown in FIG. 2, the second, low upright bent position includes the second manually bendable region 32 positioned with a smaller acute angle between the second and third rigid regions 22, 23, and includes the first manually bendable region 31 positioned with an obtuse angle between the first and second rigid regions 21, 22. Additionally, the bendable support platform region 33 is positioned with a first bend extending approximately ninety degrees outward from the first rigid region 21, and with a second bend to cause tip segments 37, 38 to extend substantially parallel to a surface of the first rigid region 21. Arranging the bendable support platform region 33 with first and second bends as illustrated in FIG. 3A permits the bendable support platform region 33 to cradle a lower edge and a portion of a front surface of a portable electronic device, thereby providing more secure engagement between the repositionable stand 10 and a portable electronic device while accommodating portable electronic devices of various thicknesses.

FIG. 3B is a perspective view illustration of the repositionable stand of FIG. 3A in the second, low upright bent position, and with the repositionable stand supporting a portable electronic device 100 represented in dashed lines. The portable electronic device 100 is supported from below by the bendable support platform region 33 with tip segments 37, 38 contacting a front surface of the portable electronic device 100. The portable electronic device 100 is supported from behind by the first rigid region 21. A charging and/or communication cable 102 is arranged to extend through the aperture 24 and the medial gap 39 to terminate at a plug 101 connected to a lower edge of the portable electronic device 100. The third rigid region 23 is horizontally arranged to be supported by an underlying surface, such as a table or desk.

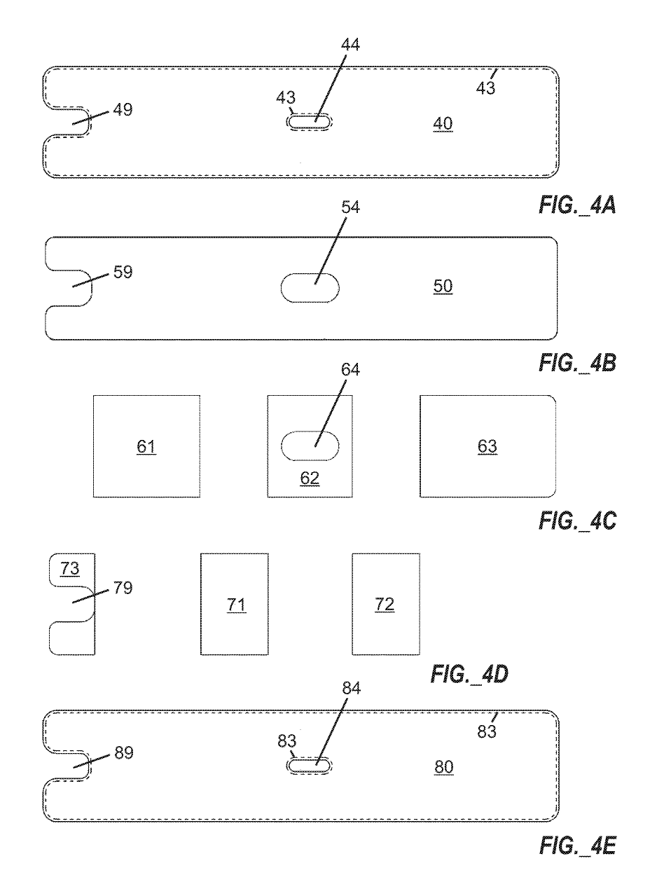

FIGS. 4A-4E illustrate top plan view illustrations of five constituent layers of a repositionable stand for a portable electronic device according to one embodiment. FIG. 4A illustrates a first (e.g., inner) covering layer 40 having a generally elongated rectangular shape (with a length substantially greater than a width, and with a width that is preferably substantially constant over the entire length), defining a central aperture 44 and defining a medial gap 49 at one end. Stitching 43 is optionally provided proximate to an outer peripheral edge of the first covering layer 40, and proximate to the central aperture 44. FIG. 4E illustrates a second (e.g., outer) covering layer 80 that is substantially identical in size and shape to the first covering layer 40. The second covering layer 80 has a generally elongated rectangular shape, defines a central aperture 84, and defines a medial gap 89 at one end. Stitching 83 is optionally provided proximate to an outer peripheral edge of the second covering layer 80, and proximate to the central aperture 84. If provided, the stitching 43 shown in FIG. 4A and the stitching 83 shown in FIG. 4E extend through both the first and second covering layers 40, 80 to join them together, such that the stitching 43 corresponds to the stitching 83. In certain embodiments, the first covering layer 40 and the second covering layer 80 are each independently selected from the group consisting of leather, rubber, woven fabric, and non-woven fabric. Wool felt may be used in certain embodiments. In certain embodiments, different covering layers of the same repositionable stand include different materials, such as leather for one covering layer, and wool felt for another covering layer.

FIG. 4B illustrates a manually bendable layer material 50 having a generally elongated rectangular shape, defining a central aperture 54, and defining a medial gap 59 at one end. In certain embodiments, the manually bendable layer material 50 may include sheet metal, such as (but not limited to) twenty-four gauge sheet steel. The manually bendable layer material 50 is preferably affixed (e.g., via adhesive bonding, welding, brazing, or the like) to and spans between the spatially separated rigid body elements 61-63 shown in FIG. 4C, thereby forming manually bendable regions between the respective rigid body elements. As shown in FIG. 4B, the manually bendable layer material 50 may include a unitary piece of material extending substantially an entire length of a repositionable stand.

In alternative embodiments, a manually bendable layer material may be provided in multiple discontinuous bendable layer material segments, such as a first manually bendable layer material segment extending between one pair of rigid body elements to form a first manually bendable region, a second manually bendable layer material segment extending between one pair of rigid body elements to form a second manually bendable region, and a third manually bendable segment extending beyond one rigid body element to form a manually bendable support platform region proximate to an end of a repositionable stand.

FIG. 4C illustrates rigid body elements 61-63 of a rigid body layer. The rigid body elements 61-63 are spatially separated from one another and are sequentially arranged along a lengthwise direction of the repositionable stand. A second (center) rigid body element 62 defines a central aperture 64 that is arranged to be registered with apertures 44, 54, and 84 as described previously. In certain embodiments, each rigid body element 61-63 comprises sheet metal (e.g., sheet steel) of a second thickness, a manually bendable layer material comprises sheet metal (e.g., sheet steel) of a first thickness, and the second thickness is greater than the first thickness. In certain embodiments, each rigid body element 61-63 comprises fourteen gauge (0.074 inch/0.188 cm) sheet steel, and the manually bendable layer material 50 comprises twenty-four gauge (0.024 inch/0.061 cm) thickness) sheet steel. In certain embodiments, each rigid body element comprises a thickness at least about 2 times greater, 3 times greater, 4 times greater, or 5 times greater than a thickness of the manually bendable layer material.

FIG. 4D illustrates padding sections 71-73 of a padding material layer. In certain embodiments, the padding comprises foam with adhesive on top and bottom. In certain embodiments, each padding section 71-73 has a thickness that is substantially equal to a thickness of the rigid body elements 61-63. Preferably, a first padding section 71 is sized and shaped to fit between the first and second rigid body elements 61, 62, and a second padding section 72 is sized and shaped to fit between the second and third rigid body elements 62, 63. The third padding section 73 defines a medial gap 79 that is arranged to be registered with corresponding medial gaps 49, 59, and 89 defined in the above-described layers 40, 50, 80.

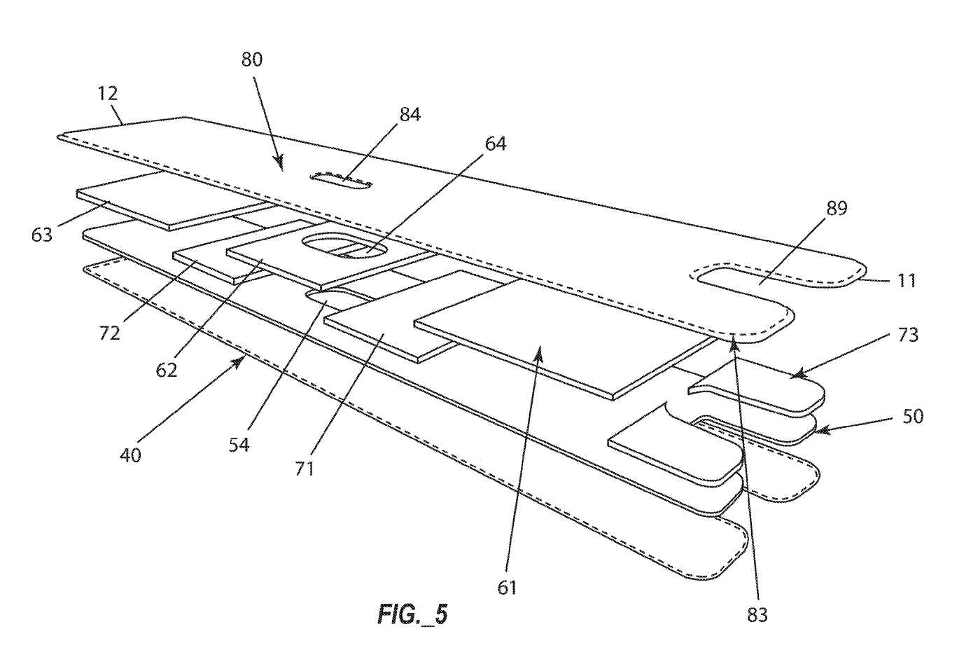

FIG. 5 is a perspective assembly view illustration of five constituent layers of a repositionable stand for a portable electronic device according to one embodiment. Starting at the bottom, a first (inner) covering layer 40 is arranged proximate to a manually bendable layer material 50. The manually bendable layer material 50 is configured to be affixed (e.g., via adhesion) to padding sections 71-73 and rigid body elements 61-63. A second (outer) covering layer 80 is arranged to contact the padding sections 71-73 and rigid body elements 61-63. Optional stitching 83 arranged along peripheral edges of the repositionable stand may join the first and second covering layers 40, 80, with the covering layers 40, 80 preferably being slightly larger than the interior layers to enable peripheral edge portions of the respective covering layers 40, 80 to be stitched to one another. In certain embodiments, stitching 83 may be omitted, with the covering layers 40, 80 being bonded to interior layers and/or one another via adhesives or other conventional means.

Although not shown in FIGS. 4A-4E or FIG. 5, in certain embodiments, one or more smoothing layers may be provided between the second (outer) covering layer 80 and the combination of the padding sections 71-73 and the rigid body elements 61-63. In certain embodiments, one or more smoothing layers may include foam or foam rubber materials. The purpose of such smoothing layer(s) is to reduce the appearance through the second covering layer 80 of transitions between the padding sections 71-73 and the rigid body elements 61-63.

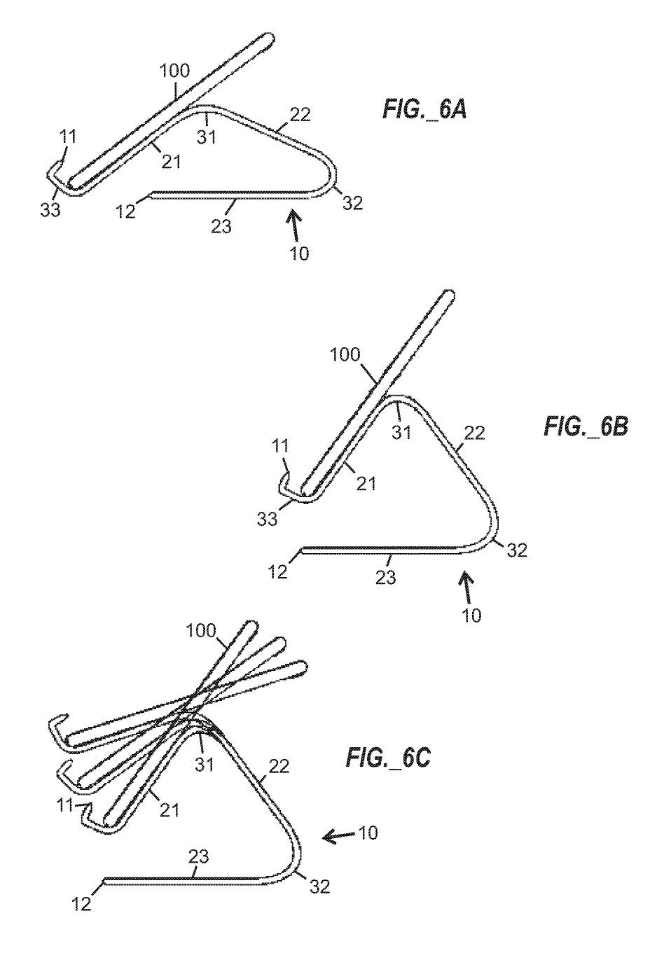

FIG. 6A is a side elevation view illustration of a repositionable stand 10 according to one embodiment in a second, low upright bent position and supporting a portable electronic device 100. The repositionable stand 10 includes a first end 11, a second end 12, three rigid regions 21-23, and three manually bendable regions 31-33 (with one embodying a bendable support platform region 33).

FIG. 6B is a side elevation view illustration of the repositionable stand 10 of FIG. 6A in a first upright bent position and supporting a portable electronic device 100. The repositionable stand 10 may be fabricated utilizing layers as described previously in connection with FIGS. 4A-5. FIG. 6C is a side elevation view illustration of the repositionable stand 10 of FIGS. 6A-6B in a range of three different positions supporting a portable electronic device 100. The manually bendable regions 31-33 are subject to being bent and repositioned with manual manipulation by a user, by simply grasping the repositionable stand 10 and applying appropriate pressure or tension. Presence of the rigid regions 21-23 eliminates the possibility of bending at locations other than the manually bendable regions 31-33, thereby avoiding potential twisting of the entire repositionable stand 10 by a user.

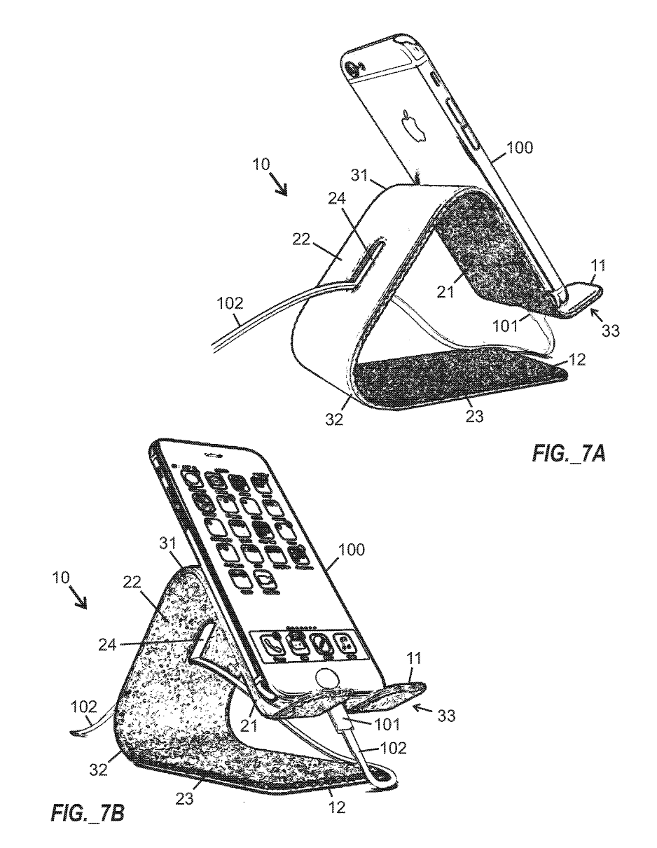

FIG. 7A is a rear perspective view illustration of a repositionable stand 10 according to one embodiment in a first upright bent position and supporting a portable electronic device 100. FIG. 7B is a front perspective view illustration of the repositionable stand 10 and portable electronic device 100 shown in FIG. 7A. As shown in FIGS. 7A-7B, the first and second manually bendable regions 31, 32 each have acute bend angles of approximately sixty degrees, and the bendable support platform region 33 includes a single bend causing the bendable support platform region 33 to extend approximately ninety degrees outward relative to the first rigid region 21. The portable electronic device 100 is supported from below by the bendable support platform region 33, and is supported from behind by the first rigid region 21, while at least one charging and/or communication cable 102 extends through the aperture 24 and the medial gap 39 to terminate at a plug 101 that is connected to a socket along a bottom edge of the portable electronic device 100. As shown in FIG. 7A, an outer surface of the repositionable stand 10 may be covered with a first covering material (e.g., leather, rubber, neoprene, smooth fabric), while an inner surface of the repositionable stand 10 may be covered with a second covering material (e.g., wool felt or other fabric) that differs from the first covering material. Preferably the inner surface of the repositionable stand may include a soft and/or absorbent material to provide beneficial tactile feel to the user and/or prevent slippage by the user when the user grasps an inner surface of the repositionable stand 10.

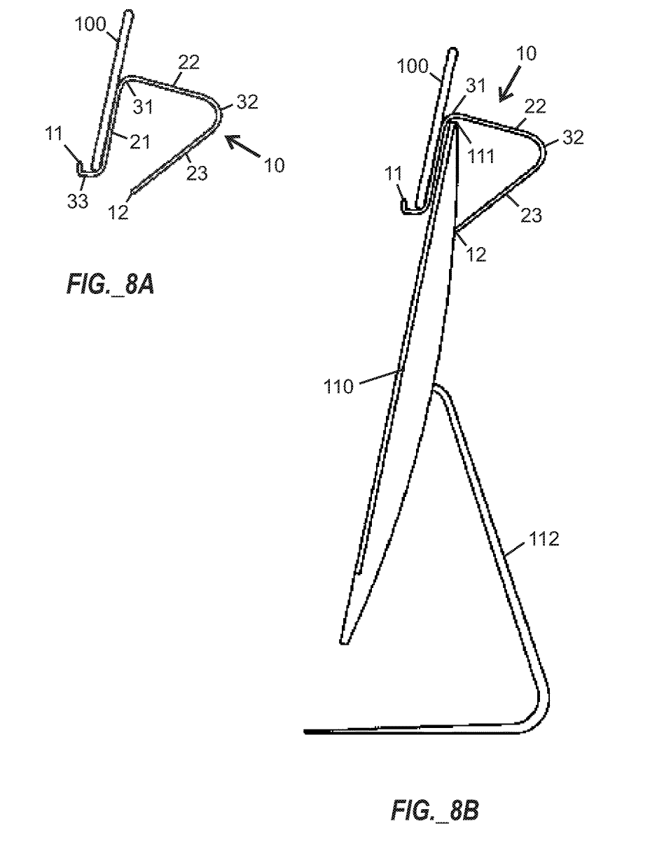

FIG. 8A is a side elevation view illustration of a repositionable stand 10 according to one embodiment in a third position and supporting a portable electronic device 100. The repositionable stand 10 includes a first end 11, a second end 12, three rigid regions 21-23, and three manually bendable regions 31-33 (with one embodying a bendable support platform region 33). FIG. 8B is a side elevation view illustration of the repositionable stand 10 and portable electronic device 100 of FIG. 8A, with an inner surface along the first manually bendable region 31 of the repositionable stand 10 being supported along an upper edge 111 of a liquid crystal display (LCD) monitor 110 having an associated monitor stand 112. In this manner, the repositionable stand 10 may be manipulated by a user to suspend a portable electronic device 100 from a LCD monitor 110, or to support a portable electronic device 100 in an upright position above an underlying surface.

Upon reading the following description in light of the accompanying drawing figures, those skilled in the art will understand the concepts of the disclosure and will recognize applications of these concepts not particularly addressed herein. Those skilled in the art will recognize improvements and modifications to the preferred embodiments of the present disclosure. All such improvements and modifications are considered within the scope of the concepts disclosed herein and the claims that follow.

What is claimed is:

1. A repositionable stand for a portable electronic device, the repositionable stand comprising:
a first end and a second end;
a plurality of rigid body elements including first, second, and third rigid body elements that are spatially separated from one another and that are sequentially arranged between the first end and the second end;
at least one manually bendable layer material; and
a support platform region proximate to the first end;
wherein the at least one manually bendable layer material spans between the plurality of rigid body elements to form (i) a first bendable region between the first rigid body element and the second rigid body element, and (ii) a second bendable region between the second rigid body element and the third rigid body element.

2. The repositionable stand of claim 1, wherein the support platform region comprises a bendable support platform region, and wherein a portion of the at least one manually bendable layer material extends beyond the first rigid body element to form the bendable support platform.

3. The repositionable stand of claim 2, wherein the at least one manually bendable layer material comprises at least one first sheet metal layer segment forming the first bendable region, at least one second sheet metal segment forming the second bendable region, and at least one third sheet metal segment forming the bendable support platform region.

4. The repositionable stand of claim 1, wherein the at least one manually bendable layer material comprises a single continuous sheet metal layer extending substantially an entire distance between the first end and the second end.

5. The repositionable stand of claim 1, wherein the at least one manually bendable layer material comprises sheet steel of a first thickness, the plurality of rigid body elements comprises sheet steel of a second thickness, and the second thickness is greater than the first thickness.

6. The repositionable stand of claim 5, wherein the at least one manually bendable layer material is affixed to the plurality of rigid body elements by adhering, brazing, or welding.

7. The repositionable stand of claim 1, further comprising a first covering material and a second covering material, wherein a combination of the at least one manually bendable layer material and the plurality of rigid body elements is arranged between the first covering material and the second covering material.

8. The repositionable stand of claim 7, wherein the first covering material and the second covering material are each independently selected from the group consisting of leather, rubber, woven fabric, and non-woven fabric.

9. The repositionable stand of claim 7, wherein:
the first rigid body element and the second rigid body element are separated by a first gap;
the second rigid body element and the third rigid body element are separated by a second gap; and
padding material is provided within the first gap between the first covering material and the second covering material, and is provided within the second gap between the first covering material and the second covering material.

10. The repositionable stand of claim 9, wherein the padding material comprises a thickness that is substantially the same as a thickness of the plurality of rigid body elements.

11. The repositionable stand of claim 1, wherein the support platform region comprises a first peripheral region and a second peripheral region separated by a medial gap proximate to the first end.

12. The repositionable stand of claim 1, wherein the second rigid body element defines an aperture, and the at least one manually bendable layer material defines an aperture that is registered with the aperture defined by the second rigid body element.

13. A repositionable stand for a portable electronic device, the repositionable stand comprising:
a first end and a second end;
a plurality of rigid body elements including first, second, and third rigid body elements that are spatially separated from one another and that are sequentially arranged between the first end and the second end; and
a manually bendable sheet metal layer affixed to the plurality of rigid body elements and extending substantially an entire distance between the first end and the second end;
wherein a first portion of the manually bendable sheet metal layer forms a first bendable region between the first rigid body element and the second rigid body element, a second portion of the manually bendable sheet metal layer forms a second bendable region between the second rigid body element and the third rigid body element, and a third portion of the manually bendable sheet metal layer extends beyond the first rigid body element to form a bendable support platform region proximate to the first end.

14. The repositionable stand of claim 13, wherein the manually bendable sheet metal layer comprises sheet steel of a first thickness, the plurality of rigid body elements comprises sheet steel of a second thickness, and the second thickness is greater than the first thickness.

15. The repositionable stand of claim 13, wherein the manually bendable sheet metal layer is affixed to the plurality of rigid body elements by adhering, brazing, or welding.

16. The repositionable stand of claim 13, further comprising a first covering material and a second covering material, wherein a combination of the manually bendable sheet metal layer and the plurality of rigid body elements is arranged between the first covering material and the second covering material.

17. The repositionable stand of claim 16, wherein the first covering material and the second covering material are each independently selected from the group consisting of leather, rubber, woven fabric, and non-woven fabric.

18. The repositionable stand of claim 16, wherein:
the first rigid body element and the second rigid body element are separated by a first gap;
the second rigid body element and the third rigid body element are separated by a second gap; and
padding material is provided within the first gap between the first covering material and the second covering material, and is provided within the second gap between the first covering material and the second covering material.

19. The repositionable stand of claim 18, wherein the padding material comprises a thickness that is substantially the same as a thickness of the plurality of rigid body elements.

20. The repositionable stand of claim 13, wherein the bendable support platform region comprises a first peripheral region and a second peripheral region separated by a medial gap proximate to the first end.

21. The repositionable stand of claim 13, wherein the second rigid body element defines an aperture, and the manually bendable sheet metal layer defines an aperture that is registered with the aperture defined by the second rigid body element.
